(19) United States
(12) Patent Application Publication
(10) Pub. No.: US 2006/0099448 A1
(43) Pub. Date: May 11, 2006

(54) Top light-emitting devices with fullerene layer

(76) Inventors: Zheng-Hong Lu, Toronto (CA); Xiaodong Feng, Toronto (CA)

Correspondence Address: Ralph A. Dowell of DOWELL & DOWELL P.C., 2111 Eisenhower Ave, Suite 406, Alexandria, VA, 22314, US

(21) Appl. No.: 11/257,393

(22) Filed: Oct. 25, 2005

Related U.S. Application Data
(63) Continuation-in-part of application No. 10/811,153, filed on Mar. 29, 2004.
(60) Provisional application No. 60/621,089, filed on Oct. 25, 2004.
(60) Provisional application No. 60/465,793, filed on Apr. 28, 2003.

(51) Int. Cl. H01L 51/52; H05B 33/02

(52) U.S. Cl. 428/690; 428/917; 313/504; 313/506; 313/112; 257/98; 257/E51.022

(57) ABSTRACT

The present invention provides a top-emission organic light emitting diode hybrid with a layer of fullerene as electron transport layer. The structure of top-emission OLED is either conventional or inverted, which includes two electrodes, a hole injection layer (HIL); a hole transport layer (HTL); an electron transport layer (ETL) including a layer of fullerene; an emissive layer, which is sandwiched between HTL and ETL. The fullerene layer functions as charge transport to reduce driving voltages.

### CROSS REFERENCE TO RELATED APPLICATIONS

This patent application relates to, and claims the priority benefit from U.S. Provisional Patent Application Ser. No. 60/621,089 filed on Oct. 25, 2004, which is incorporated herein by reference in its entirety. Furthermore, this patent application is a continuation-in-part of U.S. utility patent application Ser. No. 10/811,153 filed on Mar. 29, 2004 which claims the priority benefit from U.S. Provisional Patent Application Ser. No. 60/465,793 filed on Apr. 28, 2003, which is incorporated herein by reference in its entirety.

### FIELD OF THE INVENTION

The present invention relates to organic-based light-emitting devices (OLEDs) and more particularly the present invention relates to hybrid electroluminescence devices in which a fullerene layer is used as the electron transport layer, replacing the problematic organic electron transport layer currently used in OLEDs.

### BACKGROUND OF THE INVENTION

A typical organic light-emitting device includes an anode, an active light-emitting zone comprising one or more electroluminescent organic material(s), and a cathode. One of the electrodes is optically transmissive while the other one is optically reflective. The function of the anode is to inject positively charged particles referred to as holes into the light-emitting zone, and that of the cathode is to inject electron into the emission zone. A process involved in the recombination of the electron and the hole leads to the creation of light wave. The light wave is escaped through one of the aforementioned electrodes.

A conventional OLED structure is described in a seminal paper by Tang and VanSlyke, [C W Tang and S A VanSlyke, “Organic Electroluminescent Diode”, Applied Physics Letters, Vol. 51, 913 (1987)]. On a transparent glass substrate, an indium tin oxide (ITO) anode is covered successively with a hole transport layer consisting d of an aromatic diamine, a luminescent layer consisting of tris-(8-hydroxyquinoline)aluminum (Alq) and a metallic cathode composed of a magnesium/silver (Mg:Ag) alloy. The light is generated in the luminescent Alq layer by the recombination of the holes injected from the ITO/HTL interface and the electrons injected from the Mg:Ag/Alq interface. In this conventional structure, the light is emitted through the ITO layer and the glass substrate.

OLED display with active matrix driver contains various metal lines and thin-film transistors (TFTs) for driving pixilated diodes. The active light-emitting area or aperture is much reduced. Thus it is highly desirable to design a display with light emission not through the substrate but reflected from the substrate.

This type of device is known as top-emission structure.

U.S. Pat. No. 4,356,429 discloses inserting a hole-transport organic layer between the anode and the emission zone, and an electron-transport organic layer between the cathode and the emission zone.

It is well documented that many different types of organic molecules provide an excellent medium for the transport of holes but unfortunately they are very poor in regard to the transport of electrons. It is critical to have balance electron and hole density in the emission zone to obtain optimal device performance. In order to enhance the electron injection, low work function metals such as Ca and Mg, which provide excellent energy band-matching to that of the lowest unoccupied molecular orbital (LUMO), have been selected as cathode materials. However, the low work function metals are highly reactive that leads to fragmentation of the organic molecules when vapour phase metal atoms strike on the organic film surface [A. Turak, D. Grozea, X. D. Feng, Z. H. Lu, H. Aziz, and A. M. Hor, “Metal/Alq Interface Structures”, Appl. Phys. Lett. 81, 766 (2002).]. This limits the ability to use low work function metals as cathode. In general the cathode interface stability suffers from the fact that organic and polymeric materials contain more than one element which are very reactive. Some elements such as oxygen readily react with elements making up the cathode to form interfacial oxides, which results in electrical degradation [A. Turak, D. Grozea, X. D. Feng, Z. H. Lu, H. Aziz, and A. M. Hor, “Metal/Alq Interface Structures”, Appl. Phys. Lett. 81, 766 (2002)].

As a family member of naturally occurring allotropes of carbon, fullerene materials are known for their robust structures and superior charge transport properties. U.S. Pat. No. 5,861,219 discloses the use of fullerenes as a dopant added to a host metal complex of 5-hydroxy-quinoxaline used in organic light emitting diodes. The host metal complex of 5-hydroxy-quinoxaline is contained in the electroluminescent layer which forms the emission zone in the structure. United States Patent Publication US 2002/0093006 A1 discloses the use of a fullerene layer as the light emissive layer in an organic light emitting diode structure.

United States Patent Publication US 2003/0042846 A1 discloses the use of a fullerene layer as an electron acceptor layer in organic photovoltaic devices.

Japan Patent 3227784 and Japanese patent application 04-144479 disclose the use of fullerenes as a hole transport layer.

U.S. Pat. No. 5,171,373 discloses the use of fullerenes in solar cells. U.S. Pat. No. 5,759,725 discloses the use of fullerenes in photoconductors.

The use of fullerenes as an interface layer between the hole transport layer and the light emission layer has been disclosed by Keizo Kato, Keisuke Suzuki, Kazunari Shinbo, Futao Kaneko, Nozomu Tsuboi, Satosh Kobayashi, Toyoyasu Tadokoro, and Shinichi Ohta, Jpn. J. Appl. Phys. Vol. 42, 2526 (2003).

U.S. Pat. No. 5,776,622 issued to Hung et al. discloses an electroluminescence device including an anode, cathode and EL layer, in which the cathode layer contacts the EL layer and includes a fluoride layer in direct contact with the EL layer and a conductive layer in direct contact with the fluoride layer.

The light output of a typical OLED involves two-coupled light waves, one propagates directly through of the light-transmissive electrode, and the other reflected back from the reflective electrode and then propagate through the light-transmissive electrode. These two light waves have approximately the same amplitude and the optical interference of these two light beams dictates the total amplitude and spectral profile of the final output light waves.

It would be very advantageous to provide an organic-based electroluminescence device which provides better electronic transport in the electronic transport layer and better transport across the electronic transport layer from the cathode electrode layer to the light emission zone.

### SUMMARY OF THE INVENTION

The present invention provides a top-emission OLED in which a fullerene layer is used as the electron transport layer, replacing the current problematic organic molecule-based electron transport layer.

In one aspect of the invention there is provided a top-emission light-emitting device comprising:

a) a substrate;

b) a first electrically conductive layer defining a cathode electrode layer on the substrate;

c) an electron transport layer comprising fullerenes on the cathode electrode layer;

d) a light emissive layer located on the electron transport layer;

e) a hole injection layer on the light emissive layer; and

f) a second electrically conductive layer defining an anode electrode layer on the hole injection layer which is sufficiently transparent to allow passage therethrough of light produced in said light emissive layer.

In this aspect of the invention the device may include a hole transport layer located between the light emissive material and the hole injection layer which may be made of organic molecules which conduct holes. The fullerenes are preferably C60, C70 or combinations thereof. The device may include an interfacial layer interposed between the cathode electrode layer and the electron transport layer. The interfacial layer is preferably a fluoride compound or Li compound.

In another aspect of the invention there is provided a top-emission light-emitting device comprising:

a) a substrate;

b) a first electrically conductive layer defining an anode electrode layer on the substrate;

c) a hole injection layer on the anode electrode layer;

d) a light emissive layer located on the hole injection layer;

e) an electron transport layer comprising fullerenes on the light emissive layer; and

f) a second electrically conductive layer defining a cathode electrode layer on the electron transport layer which is sufficiently transparent to allow passage therethrough of light produced in said light emissive layer.

In this aspect of the invention the device may include a hole transport layer located between the light emissive material and the hole injection layer. The hole transport layer may be comprised of organic molecules which conduct holes. The fullerenes may be C60, C70 or combinations thereof. The device may include an interfacial layer interposed between the cathode electrode layer and the electron transport layer. The interfacial layer may be a fluoride compound or Li compound. Preferably the fluoride compound is an alkaline fluoride compound.

### BRIEF DESCRIPTION OF THE DRAWINGS

The layered structure and the light-emitting device produced according to the present invention will now be described, by way of example only, reference being made to the accompanying drawings, in which:

FIG. 1 is a sectional view of a layered structure exhibiting Ohmic behavior produced in accordance with the present invention;

FIG. 2 is a plot of current versus voltage of a bi-layer interfacial structure, namely Al/LiF/C60 (solid line), and of a simple layered structure Al/C60 produced in accordance with the present invention;

FIG. 3 is a schematic cross sectional view of a fullerene hybrid light-emitting device constructed in accordance with the present invention;

FIG. 4 is a plot of current versus voltage relationship for hybrid organic EL devices of FIG. 3 with four different thicknesses for the fullerene (C60) electron transport layer;

FIG. 5 shows plots of luminance versus voltage of hybrid organic EL devices of FIG. 3 with four different thicknesses for the fullerene (C60) electron transport layer with the four different curves corresponding to the four different thicknesses of the fullerene electron transport layer;

FIG. 6 shows the optical spectra of the hybrid organic EL devices of FIG. 3 with four different thicknesses for the fullerene (C60) electron transport layer;

FIG. 7 shows two current-voltage characteristics of Prior Art organic EL devices having electron transport layers made from conventional tris-(8-hydroxyquinoline)aluminum (Alq) organics and a thickness of 20 nm and 110 nm; and

FIG. 8 compares luminance-voltage characteristics of two OLEDs with (●), and without (∘) an embedded LiF layer, the test device structure is: glass substrate/ITO/TPD(50 nm)/Alq(25 nm)/[embeded LiF layer(0 nm (∘), 1 nm (●))]/fullerene (25nm)/LiF(0.5 nm)/Al(100 nm).

FIG. 9 shows a conventional top-emission OLED structure built in accordance with the present invention;

FIG. 10 shows an inverted top-emission OLED structure with a metal cavity built in accordance with the present invention.

FIG. 11 shows current-voltage characteristics of a TOLED device having a structure: substrate/Al(60 nm)/LiF(1 nm)/C60(10 nm)/Alq(30 nm)/NPB(60 nm)/C60(10 nm)/Ag(30 nm); and

FIG. 12 shows luminance-voltage characteristics of a TOLED device having a structure: Substrate/Al(60 nm)/LiF(1 nm)/C60(10 nm)/Alq(30 nm)/NPB(60 nm)/C60(10 nm)/Ag(30 nm).

### DETAILED DESCRIPTION OF THE INVENTION

Definitions

As used herein, the phrase “electron transport layer” means a thin-film material having a primary function of conducting or transporting electrons across the layer from one region to another region.

As used herein, the phrase “hole transport layer” means a thin-film material having a primary function to conduct holes across the layer from one region to another region.

As used herein, the phrase “light emissive layer or light-emission layer” means a thin-film material having the primary function of emitting light.

As used herein, the phrase “electroluminescence layer” means a thin-film material having a primary function of emitting light under electrical stimulation.

As used herein, the phrase “Ohmic contact (or Ohmic behavior)” means that electrical current increases linearly as a function of applied voltage across one (or more) contact interface(s) made between two (or more) different materials.

As used herein, the term “fullerene” means nanostructured carbon consisting of 60, 70, or more carbon atoms self-bonded in spherical forms which are also referred to as Buckminster fullerenes, nano bucky balls (NBB) or bucky balls (BB) in the literature. The carbon atoms may be bonded to additional atoms or functional groups.

As used herein, the phrase “hole injection layer (or hole injection electrode)” means a thin film layer having a primary function of facilitating hole injection into a hole transport layer and the hole injection layer is typically the anode.

As used herein, the phrase “interfacial contact layer”, or “interfacial layer” means an ultra-thin layer inserted between two adjacent layers to serve as an interface transition layer.

Layered Structure Exhibiting Ohmic Behavior

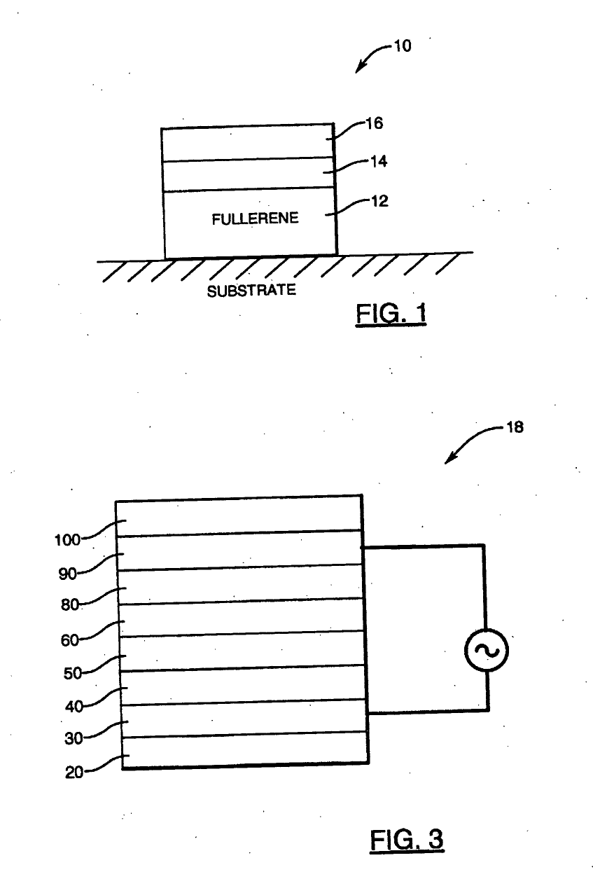

Referring first to FIG. 1 there is shown a layered structure 10 including a fullerene layer exhibiting Ohmic behavior. The layered structure 10 includes a first layer 12 comprising fullerenes and a second layer 14 of pre-selected thickness comprising a fluoride compound located on a first surface of layer 12. A third layer 16 comprising an electrically conductive material is located on the second layer 14 to which electrical contact can be made, the pre-selected thickness of the fluoride compound being selected so that the layered structure exhibits substantially Ohmic behavior across the first, second and third layers.

The fullerene may be C60, C70 or combinations thereof. Layer 12 comprising fullerenes may also include a mixture of fullerenes and organic molecules, a mixture of fullerenes and inorganic materials, polymeric fullerenes, and fullerenes chemically bonded to conducting polymers.

The fluoride compound may be alkaline fluoride compound, and preferably the alkaline fluoride compound is lithium fluoride (LiF). The pre-selected thickness of the lithium fluoride layer is in a range from about 0.2 nm to about 5 nm to give Ohmic behavior. The electrically conductive material may be Al, Cr, Cu, Ag, Au, Ni, Fe, Ni, W, Mo, Co or alloys or mixtures of for example Mg:Ag and Li:Al. Preferably the electrically conductive material is aluminum (Al).

The layered structure 10 may be applied with a second surface of the layer comprising fullerenes opposed to the first surface physically contacted to a surface of a substrate for making electrical contact between the layered structure and the substrate. The substrate may be part of an optoelectronic device such as, but not limited to, light-emitting diodes, solar cells, photodetectors etc. The substrate may also be part of an electronic device such as field-effect transistors, tunneling diodes to mention just a few.

In another embodiment of a layered structure exhibiting Ohmic behavior included is a first layer comprising fullerenes, a second layer including a low work function material located on a first surface of the layer of fullerenes. The layered structure includes a third layer which is an electrically conductive material located on the second layer to which electrical contact can be made, the low work function material being selected so that the layered structure exhibits substantially Ohmic contact across the first, second and third layers.

The fullerene may be C60, C70 or combinations thereof. The layer comprising fullerenes may also include a mixture of fullerenes and organic molecules, a mixture of fullerenes and inorganic materials, polymeric fullerenes, and fullerenes chemically bonded to conducting polymers.

The electrically conductive material may be one of Al, Cr, Cu, Ag, Au, Ni, Fe, Ni, W, Mo, Co and alloys or mixtures of Mg:Ag or Li:Al to mention just a few. The layered structure 10 may be applied with a second surface of the fullerene layer (opposed to the first surface) physically contacted to a surface of a substrate for making electrical contact between the layered structure and the substrate. The substrate may be part of an optoelectronic device such as, but not limited to, light-emitting diodes, solar cells, photodetectors etc. The substrate may also be part of an electronic device such as field-effect transistors, tunneling diodes to mention just a few.

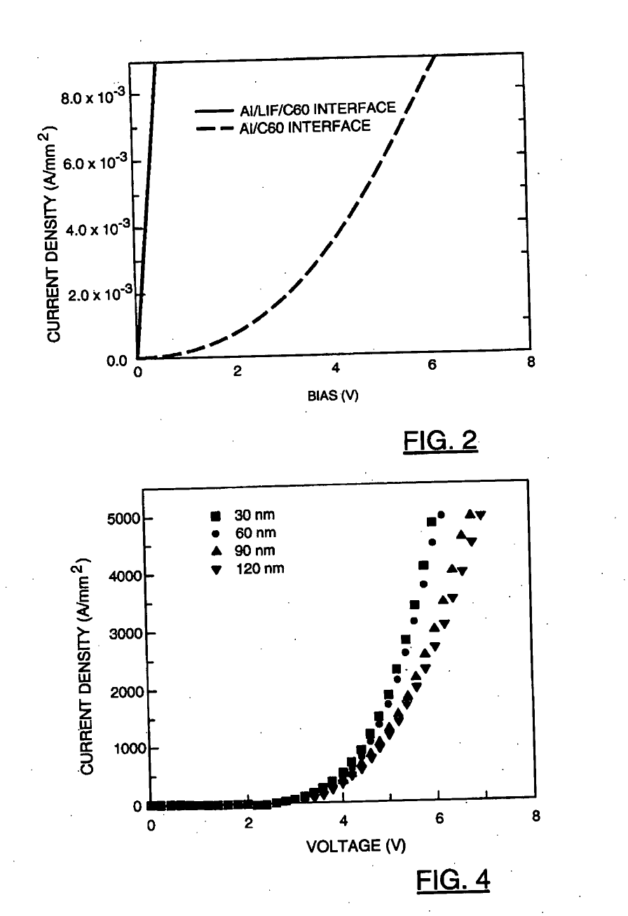

FIG. 2 shows in graphic form a current-voltage relationship of 100 nm thick C60 fullerene sandwiched between two contacting electrodes with a stacking sequence, substrate/Al/C60/Al; and substrate/Al/LiF/C60/LiF/Al. A true interface Ohmic contact is characterized by no electron current barrier present across the interface. In the present test case, the current-voltage relationship should follow a linear relationship, where the slope of the linear line is determined by the resistivity of the layer. FIG. 2 shows that Al/C60 has strong rectifying characteristics; that Al/LiF/C60 shows excellent Ohmic contact characteristics.

Electroluminescent Device

Referring to FIG. 3, an EL device 18 has been constructed to demonstrate the integration of a fullerene layer into a typical small organic molecule based device of the type disclosed in U.S. Pat. No. 4,356,429. The device 18 comprises a substrate 20, a conductive anode electrode layer 30 for hole injection, a hole transport layer 40 for hole transport, a light emissive or light-emission layer 50 capable of emitting light formed on the hole transport layer 40, a fullerene layer 60 formed on the light-emission layer 50, an outer conductive cathode layer 90 and an interfacial contact layer 80 sandwiched between fullerene layer 60 and cathode layer 90 which makes Ohmic contact with fullerene layer 60 and cathode layer 90. An optional cathode capping layer 100 made of a dielectric, such as Si oxides and nitrides, may be deposited on the cathode layer 90.

Substrate 20 may be a glass or alternatively it could be made of any material capable of providing mechanical support to thin films. It could be coated with functional thin-film transistors which may be used as electrical drivers. Substrate 20 may be optically transparent for light emitted from the light emissive layer. Alternatively, layers 80, 90 and 100 may be made of suitable materials and thickness to ensure light is coupled out of the light emissive layer 50 through these layers.

Conductive anode layer 30 is a hole injection electrode when a positive bias is applied and it may be, for example, of ITO. Electrode layer 30 may also be any other metal or alloy with a high work function. For example, anode layer 30 may be selected from high work function conducting materials including SnO₂, Ni, Pt, Au, p++ semiconductors (c-Si, a-Si, a-Si:H, poly-silicon). Additional anode materials are disclosed in U.S. Pat. No. 4,885,211 which is incorporated herein in its entirety.

Hole transport layer (HTL) 40 is preferably an organic-based layer and may be N-N′-diphenyl-N,N′-bis(3-methylphenyl)(1,1′-biphenyl)4,4′-diamine (TPD) which is commonly used as the HTL, and may have a thickness of about, but not limited to, 60 nm. It could also be any other one or more layers of organic or polymer materials capable of transporting holes and having a thickness range from about 10 nm to about 300 nm. The hole-transport layer 40 may be comprised of those materials disclosed in United States Patent Publication No. 20020180349 which is Ser. No. 10/117,812 published Dec. 5, 2002 which is incorporated herein by reference in its entirety, which application refers to U.S. Pat. Nos. 4,539,507; 5,151,629; 5,150,006; 5,141,671 and 5,846,666 which are all incorporated herein by reference in their entirety. This reference discloses different hole transport layer materials, electron transport layer materials, anode materials and cathode materials, which application refers to U.S. Pat. Nos. 4,539,507, 5,942,340 and 5,952,115 which are all incorporated herein by reference in their entirety.

Light emissive or light-emission layer 50 may be an organic electroluminescence layer comprised of, for example, tris-(8-hydroxyquinoline)aluminum (Alq) and may have a thickness of 25 nm. It could also be a layer of an organic compound capable of emitting different colors and having a thickness in the range from about 10 nm to about 100 nm. Other suitable materials useful for the light emission-layer include conjugated polymers such as poly (paraphenylene vinylene) (PPV); various members of PPV with and without pigment dyes such as disclosed in U.S. Pat. Nos. 5,294,869 and 5,151,629; rare earth metal, actinide or transition metal organic complex as disclosed in U.S. Pat. No. 6,524,727, all being incorporated herein by reference.

The active light-emission layer 50 region can also include any one or a mixture of two or more of fluorescent and phosphorescent materials including small molecules and polymers. For example, the active light-emission layer 50 may be comprised of those materials disclosed in United States Patent publication 20020180349. United States patent application Ser. Nos. 08/829,398; 09/489,144 and U.S. Pat. No. 6,057,048 also disclose materials which may be used for the light-emission layer and these references are incorporated herein in their entirety.

Electron transport layer 60 is preferably comprised of the fullerene compound C60 and has a thickness range from about 1 nm to about 300 nm, and more preferably from about 1 nm to 120 nm. The fullerene layer thickness may be selected to produce desired optical interference to generate multiple colors, colors of desired wavelength, and optimum optical power output.

Besides C60, the fullerene compound could be any other member of fullerenes such as C70, a mixture of two or more fullerene compounds such as C60:C70, a mixture of fullerenes with one or more organic molecules or polymers such as C60:Alq, C60:PPV. The electron transport layer 60 may include an organic molecule or polymer which are electron conductors mixed with the fullerenes. In addition, the electron transport layer may includes lithium fluoride (LiF) mixed with the fullerenes, or the electron transport layer may includes metal particles mixed with the fullerenes. Preferred metal particles are silver metal particles.

The interfacial layer 80 which makes contact with fullerene layer 60 is preferably made of a bi-layer of 2 nm LiF and Al. However, it will be appreciated by those skilled in the art that it could be any fluoride provided it is in direct contact with the fullerene layer. The interfacial layer 80 may be made using any low work function metals and alloys or mixtures such as Ca, Mg, Mg:Ag and Li:Al to mention just a few.

Cathode layer 90 is preferably aluminum (Al) and that which has a thickness of 100 nm has shown good behavior but other thickness may certainly be used. In addition, cathode 90 may be made of one or more layers of other well known conductive metals and/or alloys. For example, cathode 90 may be produced from one or more layers of highly conductive metals and alloys such as ITO, Al, Cr, Cu, Ag, Au, Ni, Fe, Ni, W, Mo, Co, Mg:Ag, Li:Al. An optional cathode capping layer 100 made of a dielectric, such as Si oxides and nitrides, may be deposited on the cathode by sputtering or any of the other coating techniques known to those skilled in the art.

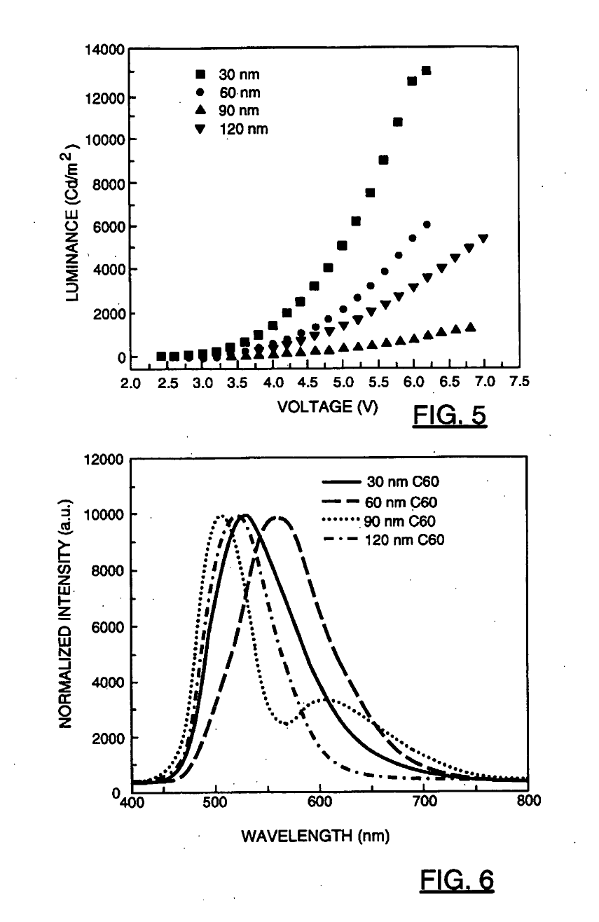

The present invention provides a hybrid light-emitting device which uses a fullerene layer as a robust electron transport layer. The electrical properties of the fullerene layer, such as high electrical conductivity and excellent electrical contact with the cathode, has made possible to maintain similar current-voltage characteristics for a wide range of thickness, as is shown in FIG. 4. The difference in optical constant of the fullerene layers and light-emitting organics permits engineering of light out of the sandwich structure as is shown in FIG. 5, and engineering of light spectral distribution as is shown in FIG. 6.

To further demonstrate the advantage of the present light-emitting device 18 using fullerene layers over conventional pure organic based light-emitting devices, FIG. 7 shows the current-voltage characteristics of prior art devices made with a conventional electron transport layer 60 made of Alq. The thickness of the Alq electron transport layer is shown to alter the current-voltage characteristics, and to increase the driving voltage by several electron volts.

It will be appreciated by those skilled in the art that the fullerene layer may comprise a mixture of two or more fullerenes, e.g. C60:C70. The fullerene layer may also comprise carbon nano-tubes, and fullerenes deposited by vapor-phase deposition.

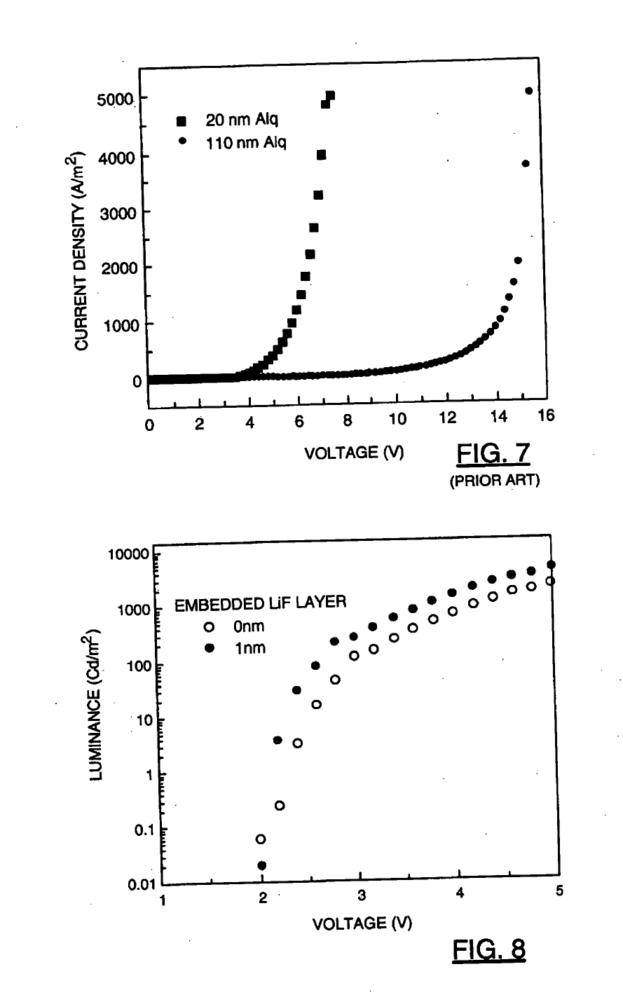

Referring again to FIG. 3 again, an alternative embodiment of the OLED display device includes inserting an interfacial layer (not shown) between fullerene layer 60 and light emissive layer 50. Based on studies by the inventors of devices which incorporate this interfacial layer, the latter provides further improvement in device performance. A thin lithium fluoride (LiF) layer of thickness (0.2-3 nm) is inserted which provides a better contact between layer 60 and layer 50 and results in a lower driving voltage for the device. FIG. 8 compares luminance-voltage characteristics of two OLEDs with (●) and without (∘) embedded LiF layer. The test device structure is: glass substrate/ITO/TPD(50 nm)/Alq(25 nm)/[embeded LiF layer(0 nm (∘), 1 nm (●))]/fullerene (25 nm)/LiF(0.5 nm)/Al(100 nm).

In another alternative embodiment of the OLED devices a layer of organic molecules with a lowest unoccupied molecular orbital (LUMO) energy of about 2 eV-3 eV and highest occupied molecular orbital (HOMO) energy of about 5-7 eV is inserted between layer 60 and layer 50. Such organic molecular layer will function as a hole blocking layer and would thus enhance exiton density in the EL layer 50 and consequently lead to a more efficient device. Non-limiting examples of such molecules include 4,4′-bis(carbazol-9-yl)-biphenyl; 2,9-dimethyl-4,7-diphenyl-1,10-phenanthroline; 1,3-Bis(5-(4-diphenylamino)phenyl-1,3,4-oxadiazol-2-yl)benzene; 3,4,5-Triphenyl-1,2,4-triazole; 3-(Biphenyl-4-yl)-4-phenyl-5-tert-butylphenyl-1,2,4-triazole; 3,5-Bis(4-tert-butylphenyl)-4-phenyl-[1,2,4]triazole; 2-(4-Biphenylyl )-5-(4-tert-butylphenyl)-1,3,4-oxadiazole; 1,3-Bis[5-(4-(1,1-dimethylethyl)phenyl)-1,3,4-oxadiazol-2-yl]benzene; 1,4-Bis(5-(4-diphenylamino)phenyl-1,3,4-oxadiazol-2-yl)benzene; 1,3.5-Tris[5-(4-(1,1-dimethylethyl)phenyl)-1,3,4-oxadiazol-2-yl]benzene.

Top Emitting Oled Device

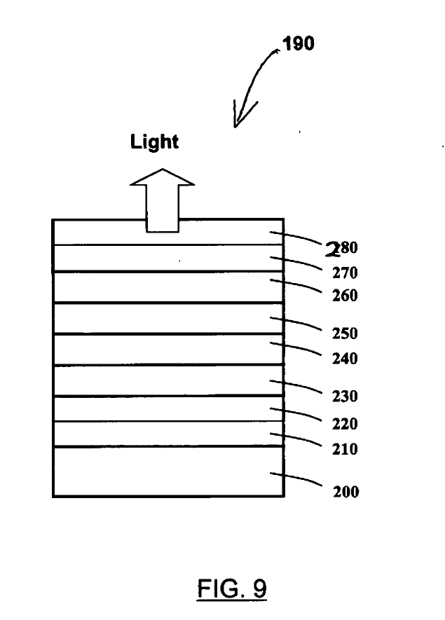

Another embodiment of an OLED device constructed in accordance with the present invention is shown generally at 190 in FIG. 9 which includes a top-emission OLED device fabricated on a substrate 200, which may be optically transparent or opaque. An anode 210 formed on a top surface of the substrate 200 is comprised of one or two layers of materials that can be deposited either by sputtering or by thermal evaporation. A hole injection layer 220, a hole transport layer 230, an emissive layer 240, a fullerene electron transport layer 250 and an interfacial layer 260 are successively evaporated on the anode 210. A cathode 270 and a protective layer 280 are deposited in sequence on the interfacial layer 260.

In an exemplary embodiment of the conventional top-emission OLED of the present invention, the substrate 200 contains TFT circuits. The cathode 270 was formed as a layer of 10-50 nm thick Ag by thermal evaporation with a 1-3 nm thick LiF interlayer 260 which is thin enough to allow the passage of light so that the light is emitted from the top cathode 270. The compositions of all the different layers of device 190 in FIG. 9 may be the same as described above for the device 18 of FIG. 3.

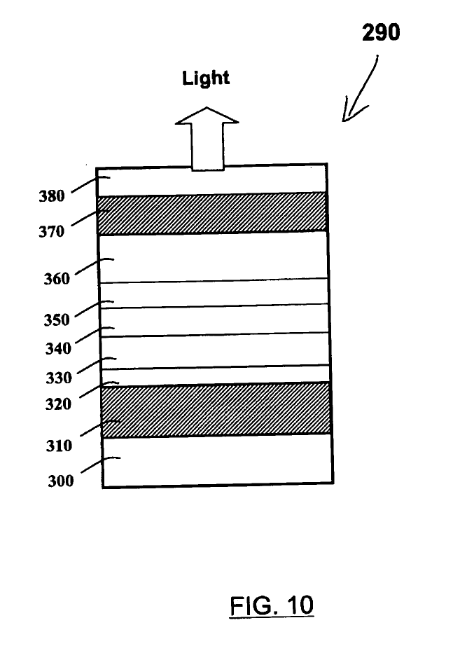

FIG. 10 shows a device structure 290 utilizing an inverted top-emission OLED fabricated on a substrate 300. The cathode 310 is deposited on the substrate 300. On top of the cathode 310, a interfacial layer 320, an electron transport layer 330, an emissive layer 340, a hole transport layer 350, and a hole injection layer 360 are stacked sequentially. The anode layer 370 is deposited on the hole injection layer 360. An optional protective coating layer 380 is deposited to encapsulate device 290. The compositions of the different layers of device 290 in FIG. 10 may be the same as described above for the device 18 of FIG. 3.

The anode material is selected to optimize the hole injection efficiency as well as to realize desired optical effect. For example, a layer of Ag is selected because of its efficient hole injection as well as low optical absorption in the visible spectrum. The reflectivity of anode may be tuned by changing the thickness of Ag, which is typically in a range of 15 to 50 nm. The total optical thickness between cathode and anode can be chosen to produce desired optical interference by tuning the thickness of HIL or/and ETL. The modification of CIE coordinates is more significant than conventional OLED. Therefore, three ideal primitive colors R, G, B can be achieved.

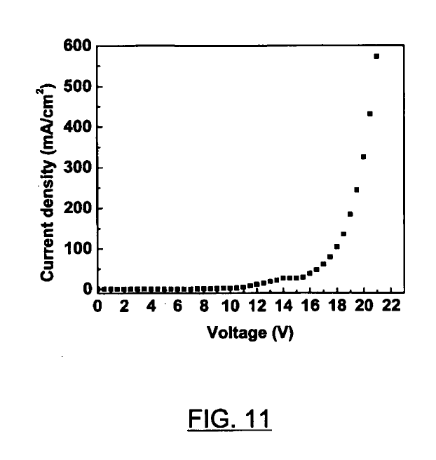

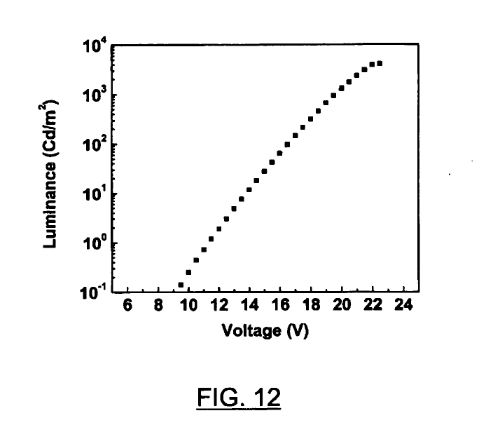

FIG. 11 shows current density as a function of bias obtained from an inverted TOLED having a structure: substrate/Al(60 nm)/LiF(1 nm)/C60(10 nm)/Alq(30 nm)/NPB(60 nm)/C60(10 nm)/Ag(30 nm). FIG. 12 shows luminance-voltage characteristics of an inverted TOLED device having a structure: Substrate/Al(60 nm)/LiF(1 nm)/C60(10 nm)/Alq(30 nm)/NPB(60 nm)/C60(10 nm)/Ag(30 nm).

Both FIGS. 11 and 12 show that inverted TOLED with reasonable device characteristics can be made using fullerene charge layers and two metal electrodes.

As used herein, the terms “comprises”, “comprising”, “including” and “includes” are to be construed as being inclusive and open ended, and not exclusive. Specifically, when used in this specification including claims, the terms “comprises”, “comprising”, “including” and “includes” and variations thereof mean the specified features, steps or components are included. These terms are not to be interpreted to exclude the presence of other features, steps or components.

The foregoing description of the preferred embodiments of the invention has been presented to illustrate the principles of the invention and not to limit the invention to the particular embodiment illustrated. It is intended that the scope of the invention be defined by all of the embodiments encompassed within the following claims and their equivalents.

Therefore what is claimed is:

1. A top-emission light-emitting device comprising:
a) a substrate;
b) a first electrically conductive layer defining a cathode electrode layer on the substrate;
c) an electron transport layer comprising fullerenes on the cathode electrode layer;
d) a light emissive layer located on the electron transport layer;
e) a hole injection layer on the light emissive layer; and
f) a second electrically conductive layer defining an anode electrode layer on the hole injection layer which is sufficiently transparent to allow passage therethrough of light produced in said light emissive layer.

2. The top-emission light-emitting device of claim 1 including a hole transport layer located between the light emissive material and the hole injection layer.

3. The top-emission light-emitting device of claim 2 wherein said hole transport layer is comprised of organic molecules which conduct holes.

4. The top-emission light-emitting device of claim 2 wherein said hole transport layer has a thickness in a range from about 1 nm to about 300 nm.

5. The top-emission light-emitting device of claim 1 wherein the cathode electrode layer is comprised of a material selected from the group consisting of Al, Li, Ca, Cr, Mg, Ag, metal alloys and layered metals.

6. The top-emission light-emitting device of claim 5 wherein said metal alloys are Al:Li or Mg:Ag, and wherein said layered metal is Cr/Al.

7. The top-emission light-emitting device of claim 1 wherein the anode electrode layer is comprised of a material selected from the group consisting of ITO, Ag, Au, Ni, Pt, and a layered structure Ag/ITO.

8. The top-emission light-emitting device of claim 1 wherein the fullerenes are selected from the group consisting of C60, C70 and combinations thereof.

9. The top-emission light-emitting device of claim 1 including an interfacial layer interposed between the cathode electrode layer and the electron transport layer.

10. The top-emission light-emitting device of claim 9 wherein the interfacial layer is a fluoride compound or Li compound.

11. The top-emission light-emitting device of claim 10 wherein the fluoride compound is an alkaline fluoride compound.

12. The top-emission light-emitting device of claim 11 wherein said the alkaline fluoride compound is lithium fluoride (LiF).

13. The top-emission light-emitting device of claim 11 wherein the fluoride compound is calcium fluoride (CaF₂).

14. The top-emission light-emitting device of claim 9 wherein the thickness of the interfacial layer is from about 0.1 nm to about 10 nm.

15. The top-emission light-emitting device of claim 2 wherein the hole injection layer is a material selected from the group consisting of m-TDATA, CuPc, ZnPc, InClPc,VOPc,1-TNATA, 2-TNATA, 6T, pentacene, and fullerenes.

16. The top-emission light-emitting device of claim 2 wherein the hole injection layer is comprised of a p-type doping material.

17. The top-emission light-emitting device of claim 1 wherein the electron transport layer includes an organic molecule or polymer which are electron conductors mixed with the fullerenes.

18. The top-emission light-emitting device of claim 2 wherein the thickness of the hole injection layer is in the range of about 1 to 200 nm.

19. The top-emission_light-emitting device of claim 1 including a lithium fluoride (LiF) layer of thickness from about 0.2 nm to about 3 nm located between the electron transport layer comprising fullerenes and the light emissive layer.

20. The top-emission light-emitting device of claim 1 including a hole-blocking layer comprised of organic molecules interposed between the electron transport layer and the light emissive layer.

21. The top-emission light-emitting device of claim 20 wherein said organic molecules are selected from the group with a LUMO energy level of about 2 eV to about 3 eV and HOMO energy of about 5.7 eV to about 7.5 eV.

22. The top-emission light-emitting device of claim 20 wherein the organic molecules are selected from the group consisting of 4,4′-bis(carbazol-9-yl)-biphenyl; 2,9-dimethyl-4,7-diphenyl-1,10-phenanthroline; 1,3-Bis(5-(4-diphenylamino)phenyl-1,3,4-oxadiazol-2-yl)benzene; 3,4,5-Triphenyl-1,2,4-triazole; 3-(Biphenyl-4-yl)-4-phenyl-5-tert-butylphenyl-1,2,4-triazole; 3,5-Bis(4-tert-butylphenyl)-4-phenyl-[1,2,4]triazole; 2-(4-Biphenylyl)-5-(4-tert-butylphenyl)-1,3,4-oxadiazole; 1,3-Bis[5-(4-(1,1-dimethylethyl)phenyl)-1,3,4-oxadiazol-2-yl]benzene; 1,4-Bis(5-(4-diphenylamino)phenyl-1,3,4-oxadiazol-2-yl)benzene; and 1,3.5-Tris[5-(4-(1,1-dimethylethyl)phenyl)-1,3,4-oxadiazol-2-yl]benzene.

23. The top-emission_light-emitting device of claim 1 wherein the substrate is selected from the group consisting of glass, plastic plate, semiconductor wafer, and a metal sheet with an insulating layer on a top surface of said substrate.

24. The top-emission light-emitting device of claim 1 including a protective coating deposited on the surface of the anode electrode layer.

25. A top-emission light-emitting device comprising:
a) a substrate;
b) a first electrically conductive layer defining an anode electrode layer on the substrate;
c) a hole injection layer on the anode electrode layer;
d) a light emissive layer located on the hole injection layer;
e) an electron transport layer comprising fullerenes on the light emissive layer; and
f) a second electrically conductive layer defining a cathode electrode layer on the electron transport layer which is sufficiently transparent to allow passage therethrough of light produced in said light emissive layer.

26. The top-emission light-emitting device of claim 25 including a hole transport layer located between the light emissive material and the hole injection layer.

27. The top-emission light-emitting device of claim 26 wherein said hole transport layer is comprised of organic molecules which conduct holes.

28. The top-emission light-emitting device of claim 27 wherein said hole transport layer has a thickness in a range from about 1 nm to about 300 nm.

29. The top-emission light-emitting device of claim 25 wherein the anode electrode layer is comprised of a material selected from the group consisting of Ag, Au Ni, Cr, Pt, and layered structures Cr/ITO, Al/ITO, and Cr/Pt.

30. The top-emission_light-emitting device of claim 1 wherein the cathode electrode layer is comprised of a material selected from the group consisting of Al, Li, Ca, Cr, Mg, Ag, alloys Al:Li and Mg:Ag), and layered metals Al/Ag.

31. The top-emission light-emitting device of claim 1 wherein the fullerenes are selected from the group consisting of C60, C70 and combinations thereof.

32. The top-emission light-emitting device of claim 1 including an interfacial layer interposed between the cathode electrode layer and the electron transport layer.

33. The top-emission_light-emitting device of claim 32 wherein the interfacial layer is a fluoride compound or Li compound.

34. The top-emission_light-emitting device of claim 33 wherein the fluoride compound is an alkaline fluoride compound.

35. The top-emission light-emitting device of claim 34 wherein said the alkaline fluoride compound is lithium fluoride (LiF).

36. The top-emission_light-emitting device of claim 34 wherein the fluoride compound is calcium fluoride (CaF₂).

37. The top-emission light-emitting device of claim 32 wherein the thickness of the interfacial layer is from about 0.1 nm to about 10 nm.

38. The device of claim 1 wherein a total optical thickness between said anode and cathode electrode layers is selected to produce desired optical interference to generate substantially ideal CIE coordinates for displays.

39. The device of claim 25 wherein a total optical thickness between said anode and cathode electrode layers is selected to produce desired optical interference to generate substantially ideal CIE coordinates for displays.
